(19) United States
(12) Patent Application Publication
(10) Pub. No.: US 2026/0063839 A1
(43) Pub. Date: Mar. 5, 2026

(54) SYSTEM AND METHOD FOR A SILICON PHOTONIC BRIDGE IN AN ELECTRONIC PACKAGE

(71) Applicant: MIXX TECHNOLOGIES, INC., San Jose, CA (US)

(72) Inventors: Rebecca Kayla Schaevitz, Sunnyvale, CA (US); Vivek Raghuraman, San Jose, CA (US)

(73) Assignee: MIXX TECHNOLOGIES, INC., San Jose, CA (US)

(21) Appl. No.: 19/319,184

(22) Filed: Sep. 4, 2025

Related U.S. Application Data
(60) Provisional application No. 63/690,748, filed on Sep. 4, 2024.

(51) Int. Cl. G02B 6/12; G02B 6/13; H01L 25/16

(52) U.S. Cl. CPC G02B 6/12004; G02B 6/13; H10W 90/00

(57) ABSTRACT

A silicon photonic bridge and method of manufacturing an integrated circuit semiconductor package may be provided. The system may include an interposer layer formed from a combination of organic and inorganic materials. The silicon photonic bridge may be embedded within the interposer layer. The silicon photonic bridge may include an electrical integrated circuit (IC) configured to process electrical signals and drive the photonic IC (PIC), and a PIC configured to process optical signals, an optical connector element(s) configured to interface the PIC with fiber and a silicon bridge configured to interface between an ASIC integrated on top of the interposer with the EIC. A silicon photonic bridge may be electrically and optically enabled to convert the electrical signal from the ASIC above the interposer to an optical signal going into fiber, and vice versa. Through-silicon vias (TSVs) may extend through the optical engine.

### RELATED APPLICATION

This application claims the benefit of U.S. Provisional Application No. 63/690,748, filed September 4, 2024, the disclosure of which is incorporated herein by reference in its entirety for all purposes.

### BACKGROUND

Unless otherwise indicated herein, the materials described herein are not prior art to the claims in the present application and are not admitted to be prior art by inclusion in this section.

The rapid advancement of semiconductor technology and artificial intelligence requirements has led to increasingly complex packaging requirements, particularly as the demand for higher performance, lower power consumption, and increased data transfer speeds continues to grow. 2.5D and 3D packaging methods, such as silicon interposers, Chip-on-Wafer-on-Substrate (CoWoS), embedded multi-die interconnect bridge (EMIB), Foveros, Fan-Out Embedded Bridge (FOEB), Fan-Out Chip-on-Substrate-Bridge (FOCoS-Bridge), Integrated Fan Outs (InFO), I-Cube, X-Cube, which involve placing multiple chips side-by-side or stacked, have been adopted due to their ability to integrate diverse functions within a single package and improve on-chip communications. However, the need to further improve off-chip communications through increased number of links as well as higher bandwidth is becoming more challenging. Existing solutions, relying primarily on electrical interconnects, are limited by the SerDes beachfront, signal integrity challenges, pin-out density and latency, which limits the number and distance of these links, especially as lane rates increase beyond 100 Gbps. To alleviate this challenge, optical engines integrated in package are poised to be the next default standard for off-package communication. However, the ability to integrate optical communication capabilities within these packages has presented significant challenges.

The subject matter claimed in the present disclosure is not limited to embodiments that solve any disadvantages or that operate only in environments such as those described above. Rather, this background is only provided to illustrate one example technology area where some embodiments described in the present disclosure may be practiced.

### SUMMARY

The embodiments described herein relate generally to a silicon photonic bridge integrated directly into the interposer or similar layer of a 2.5D semiconductor package replacing a more typical silicon bridge (e.g. Local Silicon Interposer or LSI in CoWoS-L, the embedded silicon die in EMIB, etc.). The silicon photonic bridge comprises of an optical engine and a silicon bridge. The optical engine comprises both electrical integrated circuits (EICs) and photonic integrated circuits (PICs) and optical connector elements. The silicon bridge facilitates the connection of electrical signals between a core application specific integrated circuit (ASIC) and the optical engine. The interposer layer is comprised of organic and inorganic material, which we will refer to as a hybrid interposer. By embedding the silicon photonic bridge into a hybrid interposer, the embodiments herein not only enhance data transfer capabilities but also maintain compatibility with existing semiconductor packaging processes and enable a known good interposer with optical connectivity, offering a scalable solution for future advancements in semiconductor technology.

Some embodiments include a semiconductor package with an optical engine and an embedded silicon bridge (together referred to as a silicon photonic bridge) within the interposer layer. The silicon photonic bridge of the embodiments herein enabling high density heterogeneous integration of packages with ASIC, high bandwidth memory (HBM), xPU, switch, and optical interconnects.

Some embodiments include a method of fabricating a silicon photonics bridge. Some embodiments capture a method and design using 2.5D integration, chip on wafer technology and redistribution layer (RDL) laminates that enables high bandwidth optical interfaces for xPU, HBM, Switch, ASIC or any other system on package without disruption to high volume manufacturing processes. The method enables the high bandwidth optical interface through integration with a multi-terabit optical engine.

The objects and advantages of the embodiments will be realized and achieved at least by the elements, features, and combinations particularly pointed out in the claims. Both the foregoing general description and the following detailed description are given as examples and are explanatory and are not restrictive of the invention, as claimed.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is noted, however, that the appended drawings illustrate only some aspects of this disclosure and the disclosure may admit to other equally effective embodiments.

To facilitate understanding, identical reference numerals have been used, where possible, to designate identical elements that are common to the figures. It is contemplated that elements and features of one embodiment may be beneficially incorporated in other embodiments without further recitation.

FIG. 1 illustrates a schematic of an exemplary optical assembly, in accordance with some embodiments;

FIGS. 2A-2C illustrate schematics of exemplary integrated circuit having an optical assembly, in accordance with some embodiments; and

FIG. 3A-3D illustrate an exemplary method of manufacturing an integrated circuit having an optical assembly, in accordance with some embodiments.

### DETAILED DESCRIPTION

The present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure.

As used herein, the singular form of “a”, “an”, and “the” include plural references unless the context clearly dictates otherwise. As used herein, the statement that two or more parts or components are “coupled” shall mean that the parts are joined or operate together either directly or indirectly (i.e., through one or more intermediate parts or components, so long as a link occurs). As used herein, “directly coupled” means that two elements are directly in contact with each other. As used herein, “fixedly coupled” or “fixed” means that two components are coupled so as to move as one while maintaining a constant orientation relative to each other. As used herein, “operatively coupled” means that two elements are coupled in such a way that the two elements function together. It is to be understood that two elements “operatively coupled” does not require a direct connection or a permanent connection between them. As utilized herein, “substantially” means that any difference is negligible, or that such differences are within an operating tolerance that are known to persons of ordinary skill in the art and provide for the desired performance and outcomes as described in one or more embodiments herein. Descriptions of numerical ranges are endpoints inclusive.

As used herein, the word “unitary” means a component is created as a single piece or unit. That is, a component that includes pieces that are created separately and then coupled together as a unit is not a “unitary” component or body. As employed herein, the statement that two or more parts or components “engage” one another shall mean that the parts exert a force against one another either directly or through one or more intermediate parts or components. As employed herein, the term “number” shall mean one or an integer greater than one (i.e., a plurality). Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

Embodiments described as being implemented in hardware should not be limited thereto, but can include embodiments implemented in software, or combinations of software and hardware, and vice-versa, as will be apparent to those skilled in the art, unless otherwise specified herein. In the exemplary embodiments described herein, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

The embodiments herein relate to an advanced packaging solution that may integrate a silicon photonic bridge that comprises of an optical engine with an integrated silicon bridge directly into the interposer layer of a 2.5D semiconductor package. The optical engine may comprise of electrical integrated circuits (EICs) and photonic integrated circuits (PICs) along with fiber connections. Such integration may leverage a combination of organic and inorganic materials within the interposer, offering significant improvements in performance, scalability, testability, and manufacturability compared to existing technologies.

The embodiments described below may incorporate a silicon photonic bridge, a novel component that serves as an interface between optical IO and the ASIC on the interposer. The silicon photonic bridge may enable seamless electrical and optical communication at the die level, allowing for high-density, high-speed interconnects that support the most demanding applications. Unlike traditional electrical-only silicon bridges, the silicon photonic bridge of the embodiment herein may also facilitate the conversion of electrical signals to optical signals within the same layer, significantly enhancing data transfer efficiency.

One advantageous feature of the embodiments described below may be the embedding of the optical engine directly into the interposer layer, which may, in some embodiments, be composed of organic and/or inorganic materials. Such embedding may include the integration of Through-Silicon Vias (TSVs) that facilitate power, ground, and low-speed signaling across the interposer while maintaining the integrity and performance of the optical paths. The embedded optical engine may support vertical light paths, allowing for both electrical and optical connections to be tested and validated during the manufacturing process from the top surface. This testing at the interposer level may be advantageous to ensure known-good interposers prior to integrating very expensive ASICs, such as graphics processing units (GPUs) and HBMs, onto the surface. This enablement may be used with the silicon photonic bridge.

Some embodiments may correspond to a method for integrating vertical light paths through the interposer without interference from surrounding electronic components. Such method may ensure that light signals may be transmitted and received efficiently, even in densely packed environments. Additionally, the TSVs may be advantageously designed and positioned to avoid any unwanted modulation of the optical signals, thus preserving signal integrity. By having higher speed signals traverse the silicon bridge portion of the silicon photonic bridge, fewer TSVs may be required which may be advantageous for a more densely packed PIC to achieve more channels (radix) in a smaller space. The optical engine of the embodiments herein may be designed to be protocol-agnostic, capable of converting various electrical protocols (such as peripheral component interconnect express (PCIe) and Ethernet) into optical-friendly formats. Such flexibility allows the embodiments described herein to be integrated into a wide range of system architectures, providing high adaptability and future-proofing for evolving technological standards.

The embodiments describe below may address the challenges of power consumption and thermal management by leveraging the silicon photonic bridge and a planar design of the IC. The optical engine may operate within the power envelope of traditional long-reach SerDes (Serializer/Deserializer) while offering superior data density and extended communication distances. Additionally, such planar design may allow for efficient heat extraction, ensuring reliable operation even in high-power applications.

Additionally advantageous, the embodiments herein may be fully compatible with existing 2.5D and 3D packaging processes, such as Taiwan Semiconductor Manufacturing Company’s (TSMC's) CoWoS-L and other industry-standard methods. For example, the silicon photonic bridge may replace the local silicon interposer (LSI) in a CoWoS-L package. As another example, the silicon photonic bridge may replace the EMIB. There are many such equivalencies amongst the various packaging modalities in advanced manufacturing. Such compatibility ensures that the silicon photonic bridge may be integrated into current manufacturing workflows without requiring significant changes or new equipment. Some embodiments described below may also utilize advanced manufacturing process steps such as those used in hybrid bonding to maintain the flatness and integrity of the interposer during the manufacturing process.

The design of the silicon photonic bridge, according to the embodiments herein, may allow for easy scalability, whether by increasing the data bandwidth per channel or by integrating additional wavelengths of light using Wavelength Division Multiplexing (WDM). The disclosure may also be designed to scale with future semiconductor process nodes, ensuring that it remains relevant as technology advances. Moreover, provisions for comprehensive testing and validation of both electrical and optical components during the manufacturing process may be contemplated herein. Such provisions ensure that fully functional, high-yield devices may be produced, reducing waste and improving overall reliability and cost.

Thus, as described in detail below, the embodiments described below offer a significant advancement in semiconductor packaging technology by integrating optical and electrical functions within a single interposer layer, providing enhanced performance, scalability, and manufacturability while maintaining compatibility with existing industry processes. Additionally, the solution may enable higher bandwidth, higher radix, lower latency and lower power interconnect, which may be used to scale artificial intelligence (AI) solutions of the future.

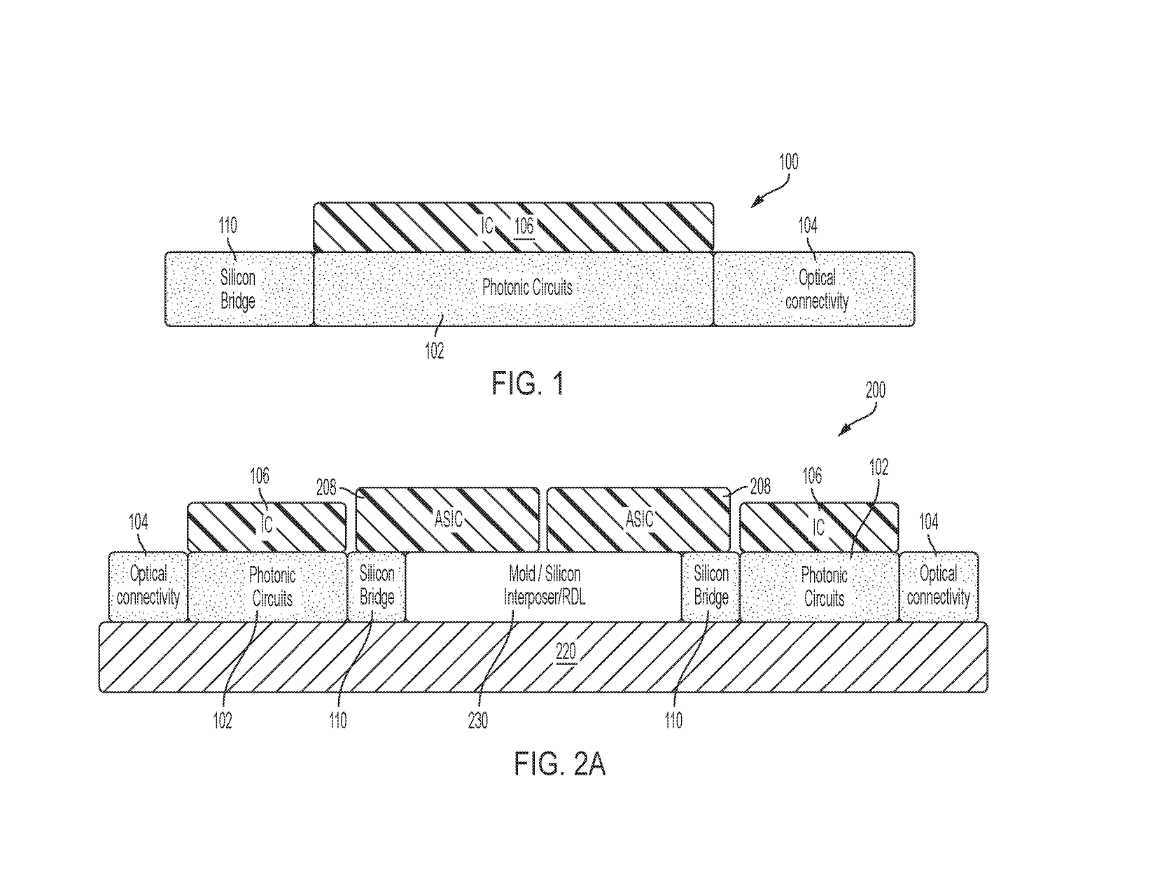

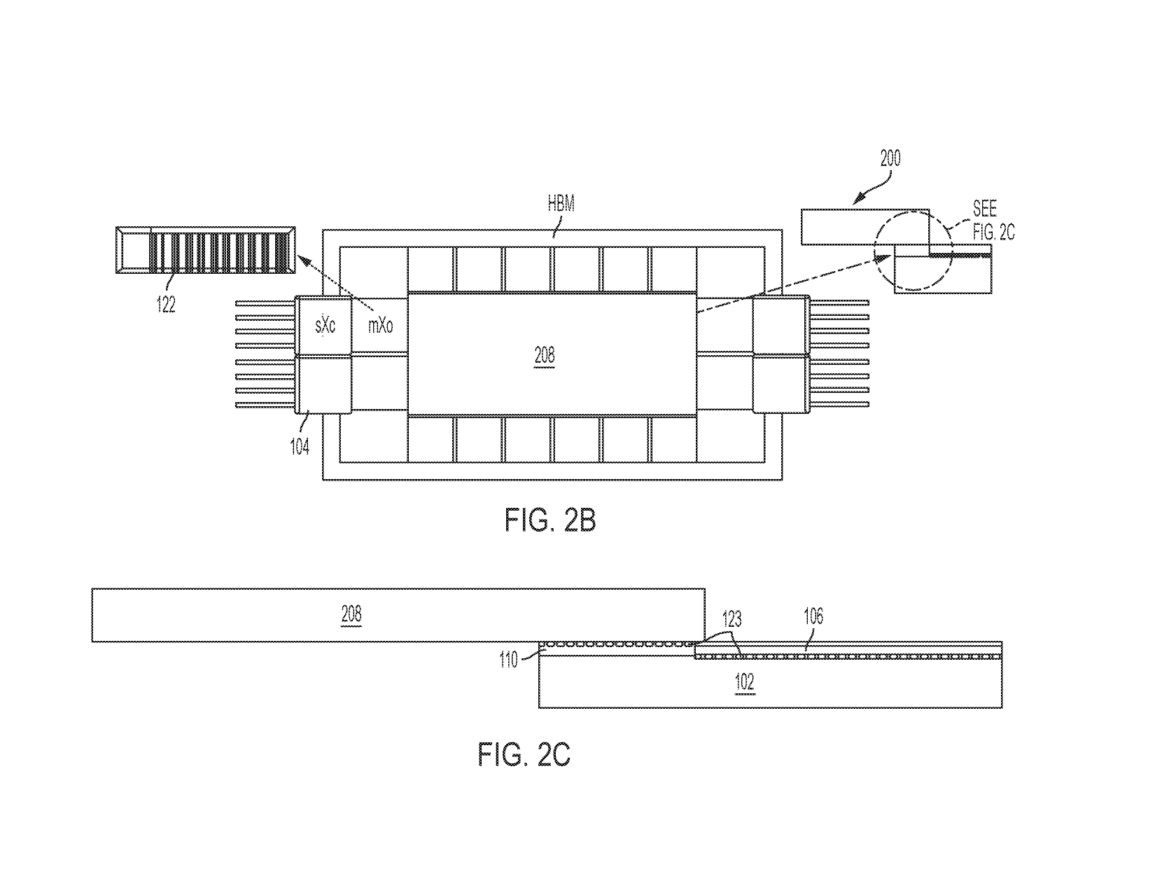

Referring now to FIGS. 1-2, FIG. 1 depicts a silicon photonic bridge (SPB) 100 that may be comprised of an optical engine with an embedded silicon bridge 110. The optical engine may be comprised of the photonic integrated circuit (PIC) 102, an electrical integrated circuit (EIC) 106 and an optical connectivity solution to fiber 104. FIG. 2A-2C shows SPB 100 embedded within a 2.5D Semiconductor Package 200 (“Semiconductor Package 200”). SPB 100 may include silicon bridge 110 and an optical engine (photonics circuits 102, electrical integrated circuits (IC) 106, and optical connectivity 104). As shown in FIG. 2B, SPB 100 includes electrical vias 122, which is describe in detail below. For purposes of this disclosure, electrical vias may refer to through-silicon vias (TSVs) or through-dielectric vias (TDVs).

For clarity, the embodiments herein may include two distinct types of vias that play distinct roles in the overall functionality of the semiconductor package. The first type, referred to as Through-Silicon Vias (TSVs) and labeled as 122, may provide power, ground, and low-speed signaling to the photonic circuit and the integrated circuit (IC) that are stacked above. These TSVs may traverse through the silicon substrate, ensuring reliable electrical connections between the layers. In addition to the TSVs (e.g., 122), there may be electrical vias or connections 123, (shown in FIG. 2C), which may be specifically designed to facilitate the silicon bridge. Unlike TSVs 122, connections 123 do not extend through the silicon substrate but instead may be integrated to support the silicon bridge's electrical connection between an ASIC above the interposer and the optical engine within the silicon photonic bridge. These connections might be through dielectric vias (TDVs), microbumps, hybrid bonding or some combination thereof.

Some silicon bridges in semiconductor packages may be used to electrically connect different dies or components above a hybrid interposer or substrate. While many such bridges facilitate the routing of electrical signals across the package, ensuring communication between the various chiplets or electrical dies, these bridges may be limited to handling electrical signals, which restricts their utility in applications requiring high-speed data transmission off package over distance or integration with optical components. SPB 100 overcomes such limitations by enabling the handling of both electrical and optical signals.

For example, such dual capability may be achieved through the integration of TSVs 122 in the SPB 100. The optical engine embedded within SPB 100 allows for the conversion of electrical signals into optical signals and vice versa. Such conversion may be advantageous for applications where data is transmitted at high speeds over longer distances with minimal loss, as optical signals may travel faster and with less attenuation compared to electrical signals. TSVs 122 may be advantageous for power, ground and low speed signaling. Additionally, connections 123 and redistribution shown in FIG. 2C may enable the high-speed interconnection between an ASIC and the optical engine as part of the silicon bridge 110.

Moreover the inclusion of SPB 100 within interposer layer 230 may also be a beneficial feature, differentiating from other technologies. For clarity, interposer layer 230 may be a beneficial component in advanced semiconductor packaging, particularly in 2.5D and 3D integrated circuit (IC) technologies. Interposer layer 230 may serve as an intermediary layer that facilitates the connection between different semiconductor dies (chips) within a single package, allowing for more complex and powerful integrated systems.

One feature of interposer layer 230 may be to provide electrical connections between multiple dies (i.e., ASICs), such as processors, memory, and other specialized chips, that are placed on top of interposer layer 230 with a higher density interconnect than can be achieved via integration on an organic substrate or printed circuit board (PCB). Such connections may include metal traces embedded within the interposer, allowing the different dies to communicate with each other. The interposer routes signals between the different dies, optimizing the signal paths to minimize delay and power consumption. By providing short, direct connections between the chips, interposer layer 230 may help improve the overall performance of IC package 200. Interposer layer 230 may also play a role in thermal management. For example, by physically separating the different dies and allowing for heat dissipation through the interposer layer, interposer layer 230 may help manage the heat generated by densely packed electronic components.

Interposer layer 230 may provide a stable mechanical platform that supports the dies and ensures that dies are securely bonded and aligned. Stability may be particularly advantageous in 2.5D packaging such as IC package 200, where multiple dies are placed side-by-side on interposer layer 230 with a very tight pitch. In some embodiments, interposer layer 230 may be silicon based, particularly in high-performance applications. Silicon interposers may offer excellent electrical and thermal properties and can be manufactured using the same processes as semiconductor wafers, making silicon interposers ideal for complex IC designs. In some embodiments, interposer layer 230 may include organic interposers made from materials including organic-based laminates (similar to those used in printed circuit boards). Organic-based laminates may be less expensive than silicon interposers but may not offer the same level of electrical performance or thermal conductivity. In some embodiments, interposer layer 230 may include glass interposers, offering a balance between cost and performance. Glass interposers may provide good electrical insulation and may be made with high precision, making them suitable for certain types of advanced packaging. And in some embodiments, the interposer might be a combination of organic-based laminates, silicon and/or glass materials.

As shown in FIG. 2, in some embodiments, for example, in 2.5D packaging (e.g., semiconductor package 200), interposer layer 230 may be implemented to place multiple dies side-by-side on a common substrate 220. Such configuration may allow for higher levels of integration without the complexities of full 3D stacking. In some embodiments, for example, in 3D packaging, interposer layer 230 may be implemented as part of a vertical stack, where multiple dies are stacked on top of each other. Interposer layer 230 may facilitate the connections between these layers, allowing for a more compact and powerful system.

As shown in FIG. 2B, interposer layer 230 may be used in conjunction with HBM to provide a wide data bus between the memory and the processing units, significantly enhancing data transfer rates and overall system performance. By reducing the distance between interconnected dies and optimizing signal paths, interposer layer 230 may improve the performance of IC package 200. Interposer layer 230 may allow for the integration of different types of dies, such as logic, memory, and specialized processors, within a single package, enabling more complex and multifunctional systems.

In some semiconductor packages, optical components may be placed on top of the interposer, which can introduce inefficiency in the signal routing, density of signals, testing and yield. As shown in FIG. 2, in contrast, the embodiments herein may integrate the silicon bridge 110, the photonic circuits 102, the optical connectivity 104 and the electrical IC 106 (together referred to as SPB 100) directly into the interposer layer 230, streamlining the design, testing, and improving the overall performance of semiconductor package 200. SPB 100 may convert seamlessly between the electrical and optical IO embedded within the interposer, ensuring that the data flow between these components and off-package is efficient and reliable.

Furthermore, SPB 100 may allow for high-density interconnects at the die level by integrating the silicon bridge 110, supporting advanced applications that use a large number of high-speed data channels without requiring more TSVs through the silicon that can impact performance of the optical engine. SPB 100 may be scalable and may be adapted to different levels of data throughput depending on the application requirements. Such scalability may be particularly advantageous, as semiconductor package 200 may be adjusted to accommodate new developments in semiconductor processing and communication standards. SPB 100 may thus serve as a versatile and powerful component within the overall semiconductor package 200.

### Vertical Light Path and Electrical Vias (e.g. TSVs)

One of the challenges in integrating optical components within a semiconductor package may be ensuring that the optical signals can be transmitted without interference from other components. In the embodiments herein, a vertical light path via the optical connectivity component 104 may be incorporated into interposer layer 230 to address this challenge. The vertical light path may be designed to allow optical signals to travel through interposer layer 230 and any additional packaging related materials such as molding compounds, connecting the photonic circuits 102 with external components such as fiber optic cables. This design ensures that the optical signals may be transmitted and received with minimal loss or distortion.

The vertical light path may be carefully engineered to avoid interference with the electrical components and signals within the interposer. The vertical light path may be achieved by isolating the optical pathways from the electrical interconnects and using materials that are transparent to the optical wavelengths used. The design may also include reflective surfaces or waveguides that direct the optical signals along the desired path, ensuring that they reach their destination without being scattered or absorbed by other materials within the interposer. This level of control over the optical signal path may be advantageous for maintaining the integrity of the data being transmitted.

The vertical light path may also be designed to enable detachability of a fiber connector with mechanical features that may integrate into the package using existing manufacturing equipment and processes. The light path and components therein, have materials that may be fully compatible to manufacturing reliability requirements, such as those published by Joint Electron Device Engineering Council (JEDEC), the Joint Electron Device Engineering Council.

In addition to the vertical light path, interposer layer 230 may include a series of electrical vias (e.g., through-silicon vias, TSVs). TSVs 122 may be vertical connections that pass through the silicon substrate (in this example passing through the PIC 102), allowing signals, power and ground to be transmitted between the different layers of semiconductor package 200. In the embodiments herein, electrical vias, such as TSVs 122 may be used to provide power, ground, and signaling connections to the optical engine. TSVs 122 may be strategically placed to avoid interference with the optical pathways, ensuring that the electrical and optical signals may coexist within the same interposer without degrading each other’s performance.

TSVs 122 in the embodiments herein may not be just standard electrical connections; they may be optimized to support the high-density, high-speed requirements of the optical engine. This includes using materials and designs that minimize interference with neighboring components, which may affect signal integrity. TSVs 122 may be also designed to be scalable, allowing for future upgrades to semiconductor package 200 without requiring a complete redesign in packaging. This flexibility may make TSVs 122 an advantageous component in the overall architecture of the package, enabling it to meet the demands of current and future semiconductor applications. FIG. 2C shows other forms of electrical vias, bumps or bonds that connect an ASIC 208 to the IC 106 as part of the SPB 100. The benefit of these shorter vias, bumps (e.g. microbumps) or bonds (e.g. hybrid bonding) above the PIC may be to reduce the number of TSVs used to traverse the silicon in the PIC layer, which may adversely affect density of the die and signal integrity. By vertically exiting above the PIC, the path length is the shortest possible to the ASIC above the interposer (approximately half the distance of traditional silicon bridges) and thus provides the best signal integrity with the lowest power required to drive the IO.

By integrating electrical functionality and optical functionality through one surface of the SPB 100, testability is dramatically improved and aligned with today’s manufacturing systems. Most optically enabled solutions may use two side testability for the electrical and optical signals. In this design, we are ensuring single side testability, which may be useful at the wafer level when scaling the package.

### High-Density Integration and Protocol Agnosticism

The integration of the optical engine and silicon bridge 110 (SPB100) within interposer layer 230 may allow for an unprecedented level of high-density interconnects in semiconductor packaging. High-density integration may be advantageous for modern applications such as AI, high-performance computing (HPC), and data centers communication, where massive amounts of data may need to be processed and transmitted quickly. The hybrid bonding techniques used in the embodiments herein may enable the precise alignment of electrical and optical components, ensuring interconnects are both dense and reliable. Similarly, packaging techniques using microbumps may enable high density and high throughput to scale the package.

Described in detail further below, a hybrid bonding process may involve creating connections at a microscopic level, with precision alignment to ensure that each connection is made without short circuits or signal degradation. This process may also be advantageous for achieving the high-density interconnects required by the optical engine, as it allows for the close packing of multiple data channels within a small area. The result is a semiconductor package that may handle large amounts of data with minimal delay, making it ideal for applications where speed and efficiency are paramount.

Another significant advantage of the embodiments herein may be protocol agnosticism. In semiconductor packaging, protocol agnosticism may refer to the ability to support multiple communication protocols without requiring changes to the hardware. SPB 100 in the embodiments herein may convert various electrical protocols, such as PCIe, Ethernet, and others, into optical signals. This conversion may be done seamlessly within SPB 100, allowing semiconductor package 200 to be used in a wide range of applications without the need for specialized hardware for each protocol.

Protocol agnosticism may provide significant flexibility for system designers, as such flexibility allows the same semiconductor package to be used in different systems with varying communication requirements. Protocol agnosticism may also future proof the embodiments herein, as new protocols may be supported through software or firmware updates without requiring changes to the physical hardware. Such versatility may make the SPB 100 a highly adaptable solution for modern and future semiconductor applications, where the ability to support multiple communication standards may be increasingly advantageous.

### Compatibility with Existing Manufacturing Processes

One of the advantageous aspects of the embodiments herein may be its compatibility with existing 2.5D and 3D packaging processes, such as TSMC’s CoWoS-L (Chip on Wafer on Substrate – Local Silicon Interposer) and similar techniques used by other semiconductor or OSAT manufacturers. Such compatibility may be advantageous for ensuring that SPB 100 may be integrated into existing production lines without requiring significant modifications or the introduction of new equipment. By aligning SPB 100 with established manufacturing processes, the embodiments herein may minimize disruption to the production flow and reduce the cost and complexity of adoption.

Discussed in further detail below, a method of manufacturing SPB 100 and semiconductor package 200 may take into account the various stages of the 2.5D packaging process, including wafer bonding, lithography, grinding, polishing, deposition, and etching. Each of these stages may have specific requirements for material compatibility, thermal stability, and alignment precision. For example, in some embodiments a hybrid interposer, made from a combination of organic and inorganic materials, may be configured to meet such requirements, ensuring that assembly 100 may be seamlessly integrated into the package and improves the thermal and mechanical stresses encountered during the manufacturing process.

Furthermore, SPB 100 may be configured for scalability with future semiconductor process nodes. As semiconductor technology continues to advance, process nodes are shrinking, allowing the production of smaller and more powerful chips. SPB 100 may be adapted to smaller process nodes without compromising performance. Such scalability may ensure that the technology remains relevant as the industry moves towards more advanced manufacturing techniques. By ensuring compatibility with both current and future manufacturing processes, the embodiments herein may provide a pathway for widespread adoption in the semiconductor industry. The ability to integrate seamlessly with existing processes while also being adaptable to future advancements may make this technology a robust solution for high-performance semiconductor packaging.

The embodiments herein incorporate comprehensive testing capabilities that allow both electrical and optical functionalities to be validated during the manufacturing process, which is discussed further below. This dual testing capability may be a significant advancement, as dual testing ensures that components within the optical engine (a subset of the SPB 100) are functioning correctly before the final assembly, thereby reducing the likelihood of defects and improving overall yield. For example, such testing process may involve the use of both electrical and optical probes, which are integrated into the manufacturing workflow, described further below. Such probes may be configured to test the connections within the optical engine (e.g., subset of SPB 100): the vertical light paths (not shown but facilitated by the optical connectivity 104), bumps, vias or bonds and TSVs 122. The electrical probes may check for continuity, resistance, and signal integrity, ensuring that the electrical connections are functioning as intended. Meanwhile, the optical probes may test the transmission and reception of optical signals, verifying that the photonic components are correctly aligned with low loss and operating at the required wavelengths.

By enabling testability from one surface of the wafer, SPB 100 may comply with existing testing protocols and equipment. Additionally, SPB 100 may be tested at the wafer level prior to dicing and integration into the hybrid interposer. Secondly, SPB 100 may be further tested at the interposer level in the same manner as originally tested to verify no significant changes to the operation prior to placement of expensive ASICs, such as GPUs and HBMs, onto the interposer. In this way, SPB 100 may significantly improve yield, left-shift defects (i.e. optimize processes to eliminate or minimize defects earlier), and reduce overall cost to enable high volume manufacturability.

In addition to the comprehensive testing capabilities, SPB 100 and semiconductor package 200 may be configured to comply with industry standards, including those set by JEDEC, Telcordia, and other such relevant standards. Compliance with JEDEC standards may be advantageous for ensuring that semiconductor package 200 meets the standards for reliability, manufacturability, and interoperability. SPB 100 and/or semiconductor package 200 may include features that ensure the package may pass the rigorous testing and validation processes required to achieve JEDEC certification, which is advantageous for commercial adoption.

The combination of robust testing capabilities and compliance with industry standards may ensure that SPB 100 and semiconductor package 200 will perform reliably in the field. These features may also make the technology attractive to manufacturers, as they can be confident that the components will meet the high standards required for commercial semiconductor products.

### Fiber Connectivity and Wafer-Scale Processing

Fiber connectivity may be an advantageous feature of the embodiments herein, as such connectivity allows SPB 100 and/or semiconductor package 200 to interface with external fiber optic networks. This capability may be advantageous for applications that use high-speed data transmission over 1 meter, such as in data center communication. SPB 100/semiconductor package 200 are configured to support a detachable fiber connection, which simplifies the process of connecting semiconductor package 200 to external networks and ensures that the optical signals can be transmitted with minimal loss while enabling compliance with JEDEC and other relevant standards.

The integration of fiber connectivity within SPB 100/semiconductor package 200 may involve several design considerations. First, the optical pathways within the interposer may be aligned with the external fiber connections, ensuring that the optical signals may be accurately transmitted and received. This alignment may be achieved through precision manufacturing techniques, which may ensure that the optical components within the interposer are correctly positioned relative to the fiber attachment points. Additionally, the materials used in the interposer and the optical engine may be selected for their compatibility with fiber optic wavelengths, ensuring that the signals may pass through the interposer without significant attenuation.

Discussed further below, the manufacturing process for the semiconductor package 200 may also include wafer-scale processing techniques, which may be advantageous for ensuring that components are accurately aligned and connected, as well as enabling high volume throughput. Wafer-scale processing may allow for the simultaneous production and testing of multiple semiconductor packages on a single wafer, improving manufacturing efficiency and yield. This process may also include steps such as lithography, etching, polishing, deposition and bonding, which are used to create the intricate structures within the interposer and SPB 100.

Wafer-scale processing may be particularly advantageous for maintaining the high levels of precision required for performance. By ensuring that each component is manufactured and tested at the wafer level, the process minimizes the risk of defects and ensures that the final semiconductor package meets the required specifications. This approach may also enable high-volume production, making the technology suitable for large-scale deployment in commercial applications.

### Thermal Management and Planarization

Thermal management may be an advantageous feature of SPB 100 embedded in the interposer layer 230, particularly for high-performance applications that generate significant amounts of heat. In the embodiments herein, thermal management may be addressed through the integration of heat sinks and other thermal dissipation features within semiconductor package 200. With the inclusion of SPB 100, the high-speed interconnects may no longer traverse through the interposer or substrate layers, leaving significantly more space available for heat sink features. While SPB 100, which includes both electrical and photonic components, may generate heat during operation, overall the thermal impact is lower than traditional electrical interconnects due to the reduction of vertical IOs required.

The heat sinks may be strategically placed within semiconductor package 200 and above the interposer layer 230 to draw heat away from the optical engine and other advantageous components. These heat sinks may be made from materials with high thermal conductivity, such as copper or aluminum, which efficiently transfer heat away from the source. The design may also include pathways for airflow or liquid cooling, depending on the application, to further enhance heat dissipation. By maintaining a stable temperature within semiconductor package 200, these thermal management features may ensure that the SPB 100 can operate at peak performance without the risk of thermal-induced failure.

In addition to thermal management, the planarization of interposer layer 230 may be another advantageous feature of the embodiments herein. Planarization may refer to the process of creating a flat and uniform surface across the interposer, which may be advantageous for consistent lithography and the reliable bonding of additional components, such as the ASIC 208, HBMs, and/or other such components. The planarization process may involve techniques such as chemical-mechanical polishing (CMP), which may remove surface irregularities and ensures that interposer layer 230 is flat and smooth.

A flat interposer surface may be advantageous for several reasons. First, it may ensure that the lithographic processes used to pattern the interposer and other layers are consistent, reducing the risk of misalignment or defects. Second, it may facilitate the bonding of additional components, such as the system-on-chip (SoC) and other ICs, by providing a uniform surface for bonding. Finally, a flat interposer may reduce the likelihood of warpage during the assembly process, which may occur due to thermal or mechanical stresses. By ensuring that the interposer remains flat and stable, the planarization process may contribute to the overall reliability and performance of semiconductor package 200. Part of the enablement of the flatter interposer may be the reduction of electrical interconnects used through the interposer and/or substrate since they now go directly to the SPB 100 and optically out via fiber.

### Integration with System-on-Chip (SoC)

The final assembly of the semiconductor package 200 may involve the integration of a system-on-chip (SoC) and other components, creating a complete system capable of supporting high-performance applications. The SoC implementation may be an advantageous component that houses the central processing unit (CPU) or other such processing units (tensor processing unit (TPU), neural processing unit (NPU), GPU, etc., referred collectively as xPU), memory, and other advantageous functions of the system. The integration of the SoC with the SPB 100 and other components within the interposer may ensure that semiconductor package 200 may function as a cohesive and powerful system.

The integration process may involve several operations, including the precise alignment and bonding of the SoC with the interposer which has the SPB 100 embedded. This process may be advantageous for ensuring that the electrical and optical signals may flow seamlessly between the SoC and the other components. The bonding process may involve techniques such as flip-chip bonding or micro-bump bonding, which may be used to create reliable connections between the SoC and the interposer. These connections may be robust enough to withstand the mechanical and thermal stresses encountered during operation, ensuring the long-term reliability of the system.

Once the SoC is integrated, semiconductor package 200 may be capable of supporting a wide range of high-performance applications. These applications may include AI, switching, data communications, and more, where the ability to process and transmit large amounts of data quickly may be advantageous. SPB 100’s ability to convert electrical signals into optical signals and transmit them at high speeds may make it particularly well-suited for these demanding applications. The SoC’s integration with the SPB 100 embedded in the interposer layer 230 may ensure that the system may operate efficiently and effectively, providing the adequate processing power and data throughput.

Furthermore, the integration of the SoC with SPB 100 and interposer may be designed to be scalable, allowing for future upgrades and enhancements. As semiconductor technology continues to evolve, the SoC and other components may be upgraded to support new features, higher data rates, and additional optical channels. This scalability may ensure that semiconductor package 200 remains relevant and capable of meeting the demands of future applications, making it a versatile and future-proof solution for high-performance computing and communication.

### Scalability and Future Developments

Scalability may be a feature of the embodiments herein, ensuring that semiconductor package 200 may adapt to advancements in semiconductor technology and evolving industry standards. The design of SPB 100 embedded in an interposer layer 230 may allow for easy scaling to support higher data rates, additional optical channels, and new communication protocols. This scalability may be advantageous for maintaining the relevance and effectiveness of the technology in a rapidly changing technological landscape.

In some embodiments, as semiconductor process nodes continue to shrink, enabling the production of smaller and more powerful chips, the components within SPB 100 may be scaled or redesigned to match these advancements. This scaling may include reducing the size of SPB 100, increasing the density of interconnects and/or TSVs 122 and bumps, bonds or TDVs, and/or enhancing the performance of the photonic and electronic components. The ability to scale the technology with shrinking process nodes may ensure that semiconductor package 200 can take full advantage of the latest manufacturing techniques, providing higher performance and lower power consumption.

In addition to scaling with process nodes, SPB 100 may also be designed to support future communication protocols and standards. As new protocols are developed, SPB 100 may be updated to convert these protocols into optical signals, ensuring compatibility with the latest systems. This protocol agnosticism may be a significant advantage allowing semiconductor package 200 to be used in a wide range of applications without major hardware changes. The ability to support multiple protocols may also future-proof the technology, making it adaptable to the evolving needs of the industry.

Looking forward, the disclosure’s design may provide a foundation for further developments in semiconductor packaging and photonics. This may include the potential for integrating additional functionalities, such as on-chip AI accelerators, advanced memory technologies, networking configurability, and more. By building on the core innovations of SPB 100, future versions of semiconductor package 200 could offer even greater performance and versatility, addressing the needs of next-generation computing and communication systems.

### Manufacturing Process

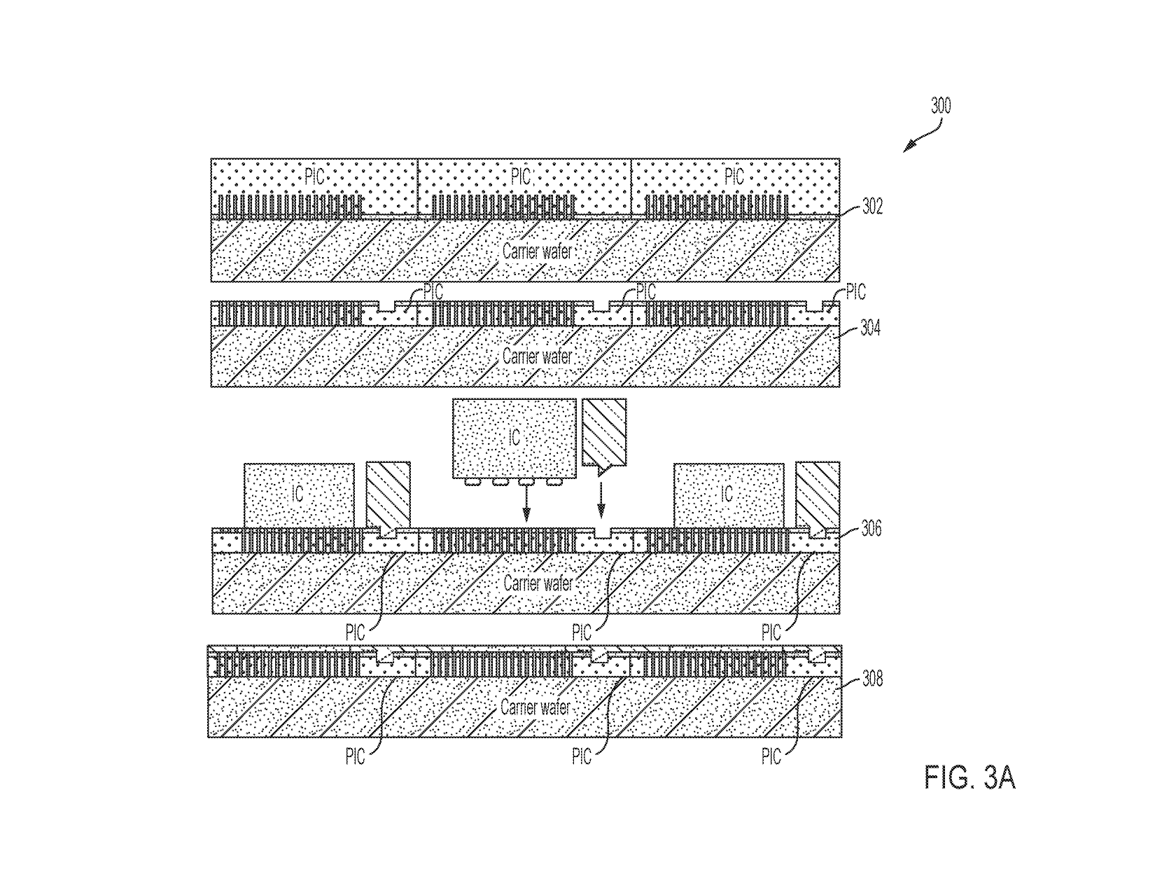

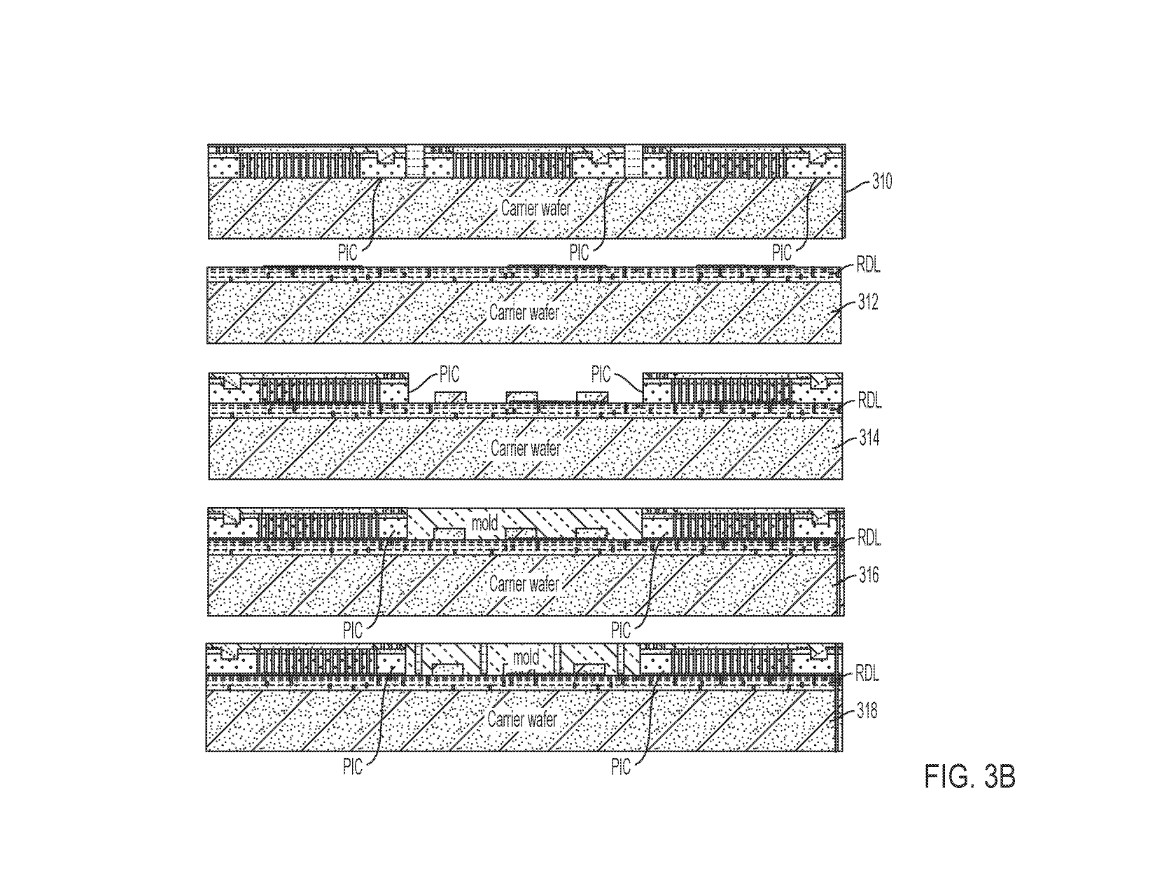

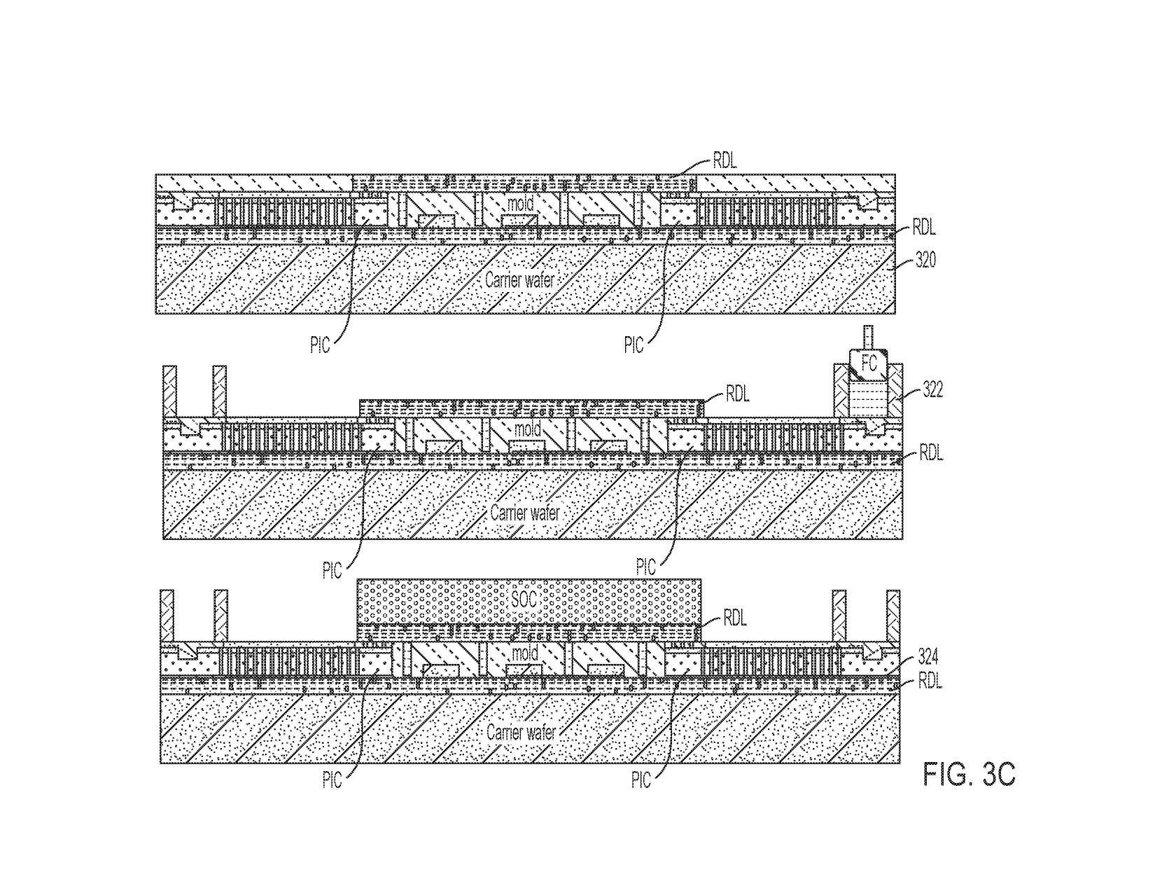

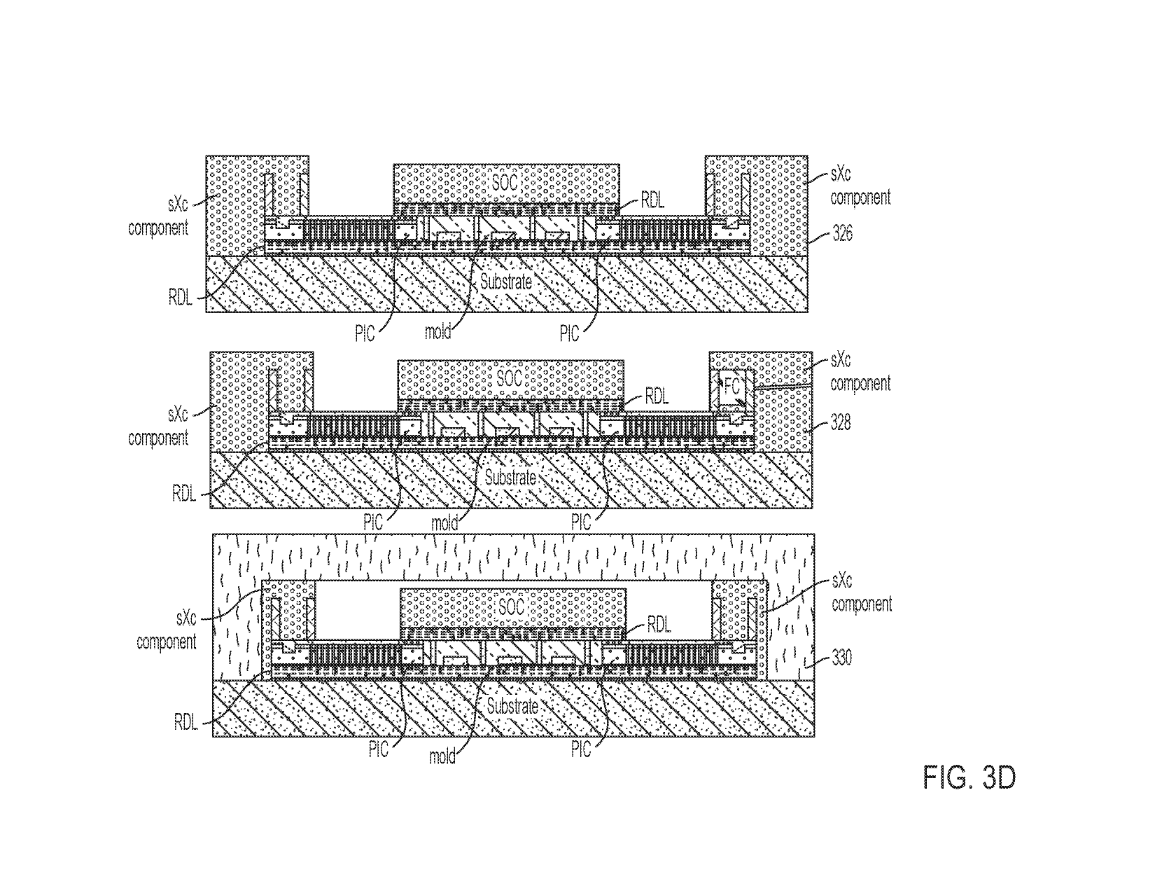

Referring now to FIGS. 3A-3D in conjunction with FIGS. 1-2, FIGS. 3A-3D depict a method 300 for manufacturing a semiconductor package with an embedded silicon photonic bridge 100 (hereinafter “semiconductor package 301”). Method 300 may ensure that the interposer is a high-yielding, fully tested, and optically enabled solution that integrates seamlessly into existing semiconductor manufacturing workflows. By maintaining control over operations of the process—from initial PIC processing to final packaging—the embodiments herein may ensure that the final product meets the highest standards of performance and reliability. The ability to integrate both electrical and optical components within a single interposer layer may represent a significant advancement in semiconductor packaging technology, offering new possibilities for high-speed data processing and communication in a compact and efficient form factor, which is discussed in detail below.

In some embodiments, method 300 may integrate an electrical integrated circuit (EIC) with a photonic integrated circuit (PIC) through a sophisticated process that involves the use of through-silicon vias (TSVs), optical turning elements, and redistribution layers (RDLs). The process may ensure that the final product (i.e., semiconductor package 301) includes a fully tested, high-yielding, optically enabled interposer that may be seamlessly integrated into existing semiconductor manufacturing workflows.

Method 300 includes initial preparation and PIC processing. For example, in some embodiments, the process may begin with a full-thickness PIC at operation 302. Initially, blind TSVs or TDVs may be introduced into the PIC from the front side. Such vias are termed "blind" because they may not extend through the thickness of the PIC at this stage and may terminate at the buried oxide (BOX) layer or within the silicon itself. Instead, the vias may be partially embedded within the PIC, serving as foundational elements for later stages of the process. Once the TSVs are in place, the PIC may be thinned from the backside to expose the TSV bond pads. In some embodiments, such thinning process may reduce the PIC's thickness to approximately or substantially 100 microns, making the TSV bond pads accessible for further processing. In other embodiments, the PIC might be thinned to the BOX layer at approximately 10-20um thickness.

After the thinning process, the PIC may be flipped back to its original orientation at operation 304. Trenches may be then created on the front side of the PIC to house the optical turning elements. Optical turning elements (e.g., mirrors) may be advantageous for directing optical signals from the PIC vertically out the surface, allowing for efficient communication between the integrated optical components and further testing during the manufacturing process. The first layer of a three-layer stack for optical connection to the fiber may be placed into these trenches as shown in operation 306.

Once the optical turning elements, made of glass or other transparent material and/or reflectivity materials, and the EIC are in place, components may be then conformably oxide-coated at operation 306. The oxide-coating may provide insulation and protection for the underlying components, ensuring such components remain intact during subsequent processing operations. It may also enable polishing of the surface for uniformity in subsequent processing operations.

In some embodiments, the glass, or other such material that is transparent to the wavelength of operation, may be thinned along with the EIC to a uniform thickness of approximately 10-30 microns as shown in operation 308. Such thickness may be advantageous when uniformly flat, which is used for the subsequent RDL application when integrated into the interposer. By operation 308, SPB 100 includes TSVs that may extend through the PIC, enabling the PIC to access power, ground and low speed signals once integrated into the interposer layer 230 and subsequently into the semiconductor package 301 as well as a light path vertically out of SPB 100. The TSVs may serve as conduits for power, ground, and signaling pathways, allowing for communication between the IC and other integrated components and testing required during manufacturing and product validation. At operation 310, the silicon bridge electrical vias may be introduced, which traverse above the PIC layer and connect directly to the IC. These vias may not extend fully through the structure but rather stop at the PIC layer, providing a direct path for electrical signals from the customer's ASIC to the EIC. At this stage, full electrical and optical testing may be performed. The dies may be then diced into individual dies ready to be placed into the photonically enabled hybrid interposer.

While FIG. 3A demonstrates one potential method for integration of TSVs, EIC, PIC, and a turning mirror element, there are other potential methods and arrangements that may enable such a configuration. For example, TDVs that connect from the top layer of the PIC to the BOX (instead of TSVs) as in FIG. 3A might be enabled. The EIC integration along with oxide deposition, thinning and planarization, may occur prior to thinning of the PIC. In this embodiment, once the PIC is thinned, the cavity for insertion of a turning mirror may be created. Subsequently, the mirror may be inserted through a wafer-to-wafer process via hybrid or fusion bonding, depending on whether the mirror wafer has electrical vias for connection. This new wafer may be thinned and inverted, such as to fill in the remaining cavity with oxide and planarize. This embodiment may also enable thickening of the buried oxide, which has other potential benefits for optical performance. Returning back to operation 310 in FIG. 3B, the silicon bridge created by these vias may form a connection pathway between the customer's ASIC, the PIC, and the IC. This pathway may be advantageous for driving the optics within the system, converting electrical signals from the ASIC into optical signals that may be processed and transmitted off-package. This innovative silicon photonic bridge may be advantageous by providing a seamless integration of optical and electrical components with a silicon bridge within a single package.

### Redistribution Layer (RDL) and Interposer Embedding

In some embodiments, once the SPB 100 is created, the next operation may involve embedding the SPB 100 into an organic interposer. At operation 312 a carrier wafer may be prepared with a RDL that includes metal and organic materials or at minimum a seed layer for later bumping (e.g. C4 bumps) to integrated onto the substrate of a package. This RDL may serve as a foundation for the subsequent pick-and-place process at operation 314, where the SPB 100, and other components such as capacitors, inductors, or other electronic elements are placed onto the RDL to form a new, optically enhanced interposer.

In some embodiments, at operation 316 the assembly may be then overmolded with a black mold compound, which may provide structural integrity and protection for the embedded components. After overmolding, a polishing operation may be performed to ensure that vias and components, including the silicon bridge and optical elements in the SPB 100, are once again revealed and co-planar. This polishing operation may be advantageous as operation 316 exposes the vias and optical elements, making such elements accessible for further processing and testing. At operation 318, vias for thermal or electrical requirements may be drilled and metalized in the mold, as shown in FIG. 3B. Alternative embodiments in the method of creation of the hybrid interposer technology may include a cavity formation and placement of the die versus the building up process described herein. The SPB 100 may be compatible with these variations as well.

### Final Assembly and Testing

As shown in FIG. 3C, in some embodiments, at operation 320, with the interposer fully assembled and polished, an additional redistribution layer may be applied to the top of the structure. The second RDL layer may be applied using wafer-scale processing techniques, which involve spinning the wafer to apply resist and other materials uniformly. The RDL may be then patterned and etched to reveal the backside of the IC and a window for optical connectors. The flatness of the structure may be maintained throughout this process, ensuring that subsequent lithography operations may be performed with high precision. In some regions, this RDL layer may be selectively removed such as using laser-based processing to enable thermal and optical windows above SPB 100. Alternatively, in other embodiments, the RDL may be created on a separate wafer with windows removed prior to transfer onto the interposer.

In some embodiments, at operation 322, a collimating element (Collimator) with a mechanical element to align fibers is placed on top of the assembly – either separately or together. The Collimator may be used for directing and collimating optical signals within the interposer to fibers that may be later be attached. Thus, the Collimator placement may be carefully timed to avoid interference with other processing operations. The Collimator may be applied using standard pick-and-place technology, ensuring that it is accurately positioned within the assembly. Once the Collimator is in place, a fiber connector may be used for top-down testing of the optical components, verifying that the optical pathways are functioning correctly, using the same mechanics that later create the functional product fiber connector, such as an upper body reflector (UBR) with integrated fibers. The Collimator, if it has good thermal properties, may also be utilized across the SPB surface to provide thermal pathways to the heat sink.

The optical connector, which may be integrated into the interposer throughout the process, may be now fully operational. The connector may include both optical and mechanical components, which are designed to interface with external systems. The final testing phase at operation 322 may involve a thorough examination of both the electrical and optical pathways within the interposer, ensuring that components are functioning as expected, thus creating a known good interposer. At operation 324, a SoC (e.g., GPU, HBM) may be placed onto the optically-enhanced interposer. It may be noted that in some embodiments, operations 302-324 may occur in different orders than described above and shown in FIGS. 3A-3D.

As shown in FIG. 3D, after the final testing at the foundry, the completed interposer may be transferred to an outsourced semiconductor assembly and test (OSAT) facility for the final stages of packaging. At the OSAT, the interposer with system on chip (SOC) may be mounted onto a substrate at operation 326, and additional features such as a lid or heat sink are attached. The final mechanics for the optical connector may also be added at this stage, ensuring that the interposer may be seamlessly integrated into larger systems. These mechanics may be used to ensure high reliability for a detachable fiber interface that aligns with standards requirements, such as those provided by Telcordia.

At operation 328, the final semiconductor assembly 301 may undergo one last round of testing, which may include both electrical and optical tests, depending on the specific requirements of the system. At this point, the final fiber connector, for example a UBR integrated with its own mechanics to mate with the package, may be used for testing. The fully packaged, optically enabled interposer may be now ready for deployment in high-performance computing, datacom, or other advanced applications and is shipped to original design manufacturer (ODM) at operation 330.

For simplicity of explanation, methods and/or process flows described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter.

In the embodiments herein, SPB 100 and/or semiconductor package 200 components (e.g., 102, 104, 106, 110, 122, 208, 220, 230) as part of or apart from the optical engine may facilitate communication with a number of processing units (e.g., xPUs), switch ASICs, memory, or other similar ASICs requiring off-chip communication. One or more aspects or features of the subject matter described herein may be realized in digital electronic circuitry, integrated circuitry, specially designed ASICs, field programmable gate arrays (FPGAs) computer hardware, firmware, software, and/or combinations thereof. These various aspects or features may include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system may include clients and servers. A client and server are generally remote from each other and interact through a communication network. The relationship of client and server arises by virtue of computer programs running on the respective computers and having a client-server relationship to each other.

These computer programs, which can also be referred to programs, software, software applications, applications, components, or code, include machine instructions for a programmable processor, and can be implemented in a high-level procedural language, an object-oriented programming language, a functional programming language, a logical programming language, and/or in assembly/machine language. As used herein, the term “machine-readable medium” (or “computer readable medium”) refers to any computer program product, apparatus and/or device, such as for example magnetic discs, optical disks, memory, and Programmable Logic Devices (PLDs), used to provide machine instructions and/or data to a programmable processor, including a machine-readable medium that receives machine instructions as a machine-readable signal. The term “machine-readable signal” (or “computer readable signal”) refers to any signal used to provide non-transitory machine readable instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example as would a processor cache or other random access memory associated with one or more physical processor cores.

To provide for interaction with a user, one or more aspects or features of the subject matter described herein can be implemented on a computer having a display device, such as for example a cathode ray tube (CRT) or a liquid crystal display (LCD) or a light emitting diode (LED) monitor for displaying information to the user and a keyboard and a pointing device, such as for example a mouse or a trackball, by which the user may provide input to the computer. Other kinds of devices can be used to provide for interaction with a user as well. For example, feedback provided to the user can be any form of sensory feedback, such as for example visual feedback, auditory feedback, or tactile feedback; and input from the user may be received in any form, including, but not limited to, acoustic, speech, or tactile input. Other possible input devices include, but are not limited to, touch screens or other touch-sensitive devices such as single or multi-point resistive or capacitive trackpads, voice recognition hardware and software, optical scanners, optical pointers, digital image capture devices and associated interpretation software, and the like.

Thus, embodiments disclosed above may introduce a groundbreaking optical engine and method for integrating both electrical and optical components within a single interposer layer, significantly advancing semiconductor packaging technology. By incorporating through-silicon vias (TSVs), silicon photonic bridges, and advanced RDL techniques, the embodiments described above may enable the seamless embedding of photonic integrated circuits (PICs) alongside traditional electrical integrated circuits (ICs). The approach describe in the embodiments above may not only enhance data processing and communication speeds but also ensure compatibility with existing manufacturing processes, allowing for a high-yield, fully tested interposer that meets industry standards.

Such innovative optically enhanced interposer may provide a scalable solution for a wide range of applications, including high-performance computing, switching or routing, and data center communication. The integration of electrical and optical functionalities within a compact package addresses the growing demand for higher bandwidth, lower power consumption, and increased integration density. By maintaining process compatibility and offering future scalability, the embodiment describe above may be positioned to play a significant role in the evolution of next-generation semiconductor devices, delivering unparalleled performance and versatility.

The embodiments described herein may be embodied in systems, apparatus, methods, computer programs and/or articles depending on the desired configuration. Any methods or the logic flows depicted in the accompanying figures and/or described herein do not necessarily require the particular order shown, or sequential order, to achieve desirable results. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. The implementations described above can be directed to various combinations and subcombinations of the disclosed features and/or combinations and subcombinations of further features noted above. Furthermore, above described advantages are not intended to limit the application of any issued claims to processes and structures accomplishing any or all of the advantages. Furthermore, any reference to this disclosure in general or use of the word “embodiment” in the singular is not intended to imply any limitation on the scope of the claims set forth below. Multiple embodiments may be set forth according to the limitations of the multiple claims issuing from this disclosure, and such claims accordingly define the embodiment(s) herein, and their equivalents, that are protected thereby.

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot be used in combination.

Although the description provided above provides detail for the purpose of illustration based on what is currently considered to be the most practical and preferred embodiments, it is to be understood that such detail is solely for that purpose and that the disclosure is not limited to the expressly disclosed embodiments, but, on the contrary, is intended to cover modifications and equivalent arrangements that are within the spirit and scope of the appended claims. For example, it is to be understood that the present disclosure contemplates that, to the extent possible, one or more features of any embodiment can be combined with one or more features of any other embodiment.

1. A system, comprising:
a layer formed from one or more of organic materials or inorganic materials, wherein the layer is one or more of an interposer layer or a substrate layer;
a silicon photonic bridge embedded within the layer, wherein the silicon photonic bridge comprises:
a photonic integrated circuit (PIC) configured to process optical signals;
an electrical integrated circuit (EIC) configured to process electrical signals and drive the PIC; and
a silicon bridge electrically coupled to the EIC to facilitate connection of electrical signals to the EIC.

2. The system of claim 1, further comprising a plurality of electrical vias extending through the PIC, the electrical vias configured to provide one or more of power, ground, or signaling connections to the one or more of the EIC or PIC.

3. The system of claim 1, wherein the silicon photonic bridge is integrated into the layer and provides an interconnection between an application specific integrated circuit (ASIC) integrated on top of the layer and an optical fiber output within the system.

4. The system of claim 3, wherein the silicon photonic bridge is configured to support a protocol-agnostic communication interface between the ASIC and the optical fiber output.

5. The system of claim 1, wherein the silicon photonic bridge includes a vertical light path integrated into the layer, wherein the vertical light path facilitates transmitting and receiving of optical signals through the layer without interference from surrounding electronic components.

6. The system of claim 1, wherein the layer is compatible with 2.5D semiconductor packaging processes.

7. The system of claim 1, wherein the silicon photonic bridge is configured to facilitate data transfer rates by using one or more wavelengths of light within the PIC.

8. The system of claim 1, wherein an optical engine is configured to support conversion of electrical signals from different protocols into corresponding optical signals within the silicon photonic bridge.

9. The system of claim 1, wherein a top surface of the layer facilitates one or more of a hybrid or fusion bonding interface with an alignment of 1 micron or less to facilitate adhesion of a collimator to the silicon photonic bridge to facilitate vertical optical coupling.

10. The system of claim 1, wherein the silicon photonic bridge is configured to optimize thermal extraction from the layer.

11. The system of claim 1, wherein the silicon photonic bridge is configured to aggregate a plurality of lower speeds channels to a single higher speed channel using a die-to-die interface converted to optical standard protocols.

12. A method of manufacturing a semiconductor package comprising a silicon photonic bridge embedded within one or more of an interposer layer or a substrate, the method comprising:
providing one or more of the interposer layer or the substrate formed from one or more of organic materials or inorganic materials;
forming a silicon photonic bridge comprising: an electrical integrated circuit (EIC), a photonic IC (PIC), optical coupling features, and a silicon bridge, wherein the silicon photonic bridge is configured to convert electrical signals into optical signals and convert optical signals into electrical signals;
embedding the silicon photonic bridge into the one or more of the interposer layer or the substrate; and
integrating a vertical light path within the interposer layer, allowing for optical signals to be transmitted and received through the interposer layer.

13. The method of claim 12, wherein the silicon photonic bridge comprises a plurality of electrical vias extending through the silicon photonic bridge, wherein the electrical vias are configured to provide one or more of power, ground, or signaling connections.

14. The method of claim 12, further comprising:
attaching a system-on-chip (SoC) to the interposer layer or the substrate via the silicon bridge embedded in the silicon photonic bridge.

15. The method of claim 12, wherein the operation of embedding the silicon photonic bridge into the one or more of the interposer layer or the substrate further comprises aligning the silicon bridge to facilitate accurate signal transmission to an application specific integrated circuit (ASIC) placed above the interposer.

16. The method of claim 12, wherein the operation of forming the silicon photonic bridge comprises using one or more of a hybrid bonding process or a fusion bonding process with an alignment of 1 microns or less.

17. The method of claim 12, wherein the testing operation includes both electrical probing and optical probing to validate the functionality of the silicon photonic bridge and the interposer.

18. The method of claim 12, further comprising the operation of adding a heat sink to the semiconductor package to dissipate heat from the silicon photonic bridge and other ASICs during operation.

19. The method of claim 12, further comprising the operation of integrating one or more of a collimator or mechanical alignment element into the semiconductor package to facilitate optical signal transmission and top-down testing.

20. The method of claim 12, wherein the method is compatible with one or more manufacturing standards set by the Joint Electron Device Engineering Council (JEDEC), Telcordia, or a combination thereof.
